(19) United States
(12) Patent Application Publication
(10) Pub. No.: US 2022/0009143 A1
(43) Pub. Date: Jan. 13, 2022

(54) POLYIMIDE COMPOSITE FILM HAVING IMPROVED SURFACE ADHESIVE STRENGTH WITH METAL LAYER AND METHOD FOR PREPARING THE SAME

(71) Applicant: PI Advanced Materials Co., Ltd., Iwol (KR)

(72) Inventors: Dong Young KIM, Iwol (KR); Dong Young WON, Iwol (KR); Jeong Yeul CHOI, Iwol (KR)

(73) Assignee: PI Advanced Materials Co., Ltd., Iwol (KR)

(21) Appl. No.: 17/292,410

(22) PCT Filed: Nov. 8, 2019
(86) PCT No.: PCT/KR2019/015158

§ 371 Date: May 7, 2021

(30) Foreign Application Priority Data
Nov. 9, 2018 (KR) 10-2018-0137415
Nov. 7, 2019 (KR) 10-2019-0141836

(51) Int. Cl. B29C 48/18; C08G 73/10; C08L 79/08; B29C 48/91; B29C 71/02; C23C 14/20; C08K 3/08

(52) U.S. Cl. CPC B29C 48/18; C08G 73/1067; C08L 79/08; B29C 48/91; B29K 2079/08; C23C 14/20; C08K 3/08; C08K 2201/003; C08L 2203/16; B29C 71/02

(57) ABSTRACT

A polyimide composite film having good adhesion to a metal layer without deterioration in mechanical properties.

### TECHNICAL FIELD

The present invention relates to a polyimide composite film having improved adhesive strength to a metal layer and a method of preparing the same.

### BACKGROUND ART

Polyimide (PI) is a polymer material that is based on a rigid aromatic backbone and an imide ring having excellent chemical stability, and has the highest level of heat resistance, chemical resistance, electrical insulation, and weather resistance, among organic materials. Thus, polyimide is catching on as an insulating material for microelectronic components requiring such properties.

Examples of the microelectronic components may include thin circuit boards that are highly-integrated and flexible in response to a trend of pursuing light weight and miniaturization of electronic products. Polyimide is widely used as an insulating film for these thin circuit boards.

Such a thin circuit board generally has a structure in which a circuit including a metal foil is formed on an insulating film, and is called “flexible metal foil-clad laminate” in a broad sense. When a thin copper plate is used as the metal foil, the thin circuit board may be called “flexible copper-clad laminate (FCCL)” in a narrower sense.

For example, the flexible metal foil-clad laminate may be fabricated by (i) a casting method in which a polyamic acid, which is a precursor of polyimide, is cast onto or applied to a metal foil, followed by imidization, (ii) a metallization method in which a metal layer is directly deposited on a polyimide film by sputtering, or (iii) a lamination method in which a thermoplastic polyimide film is bonded to a metal foil by heat and pressure. Thereamong, the metallization method is a method of producing a flexible metal foil-clad laminate by sputtering a metal, such as copper, onto a 20 μm to 50 μm thick polyimide film to sequentially deposit a tie layer and a seed layer on the polyimide film. Particularly, the metallization method is advantageous for formation of a microcircuit having a pattern pitch of 35 μm or less and is widely used to manufacture a flexible metal foil-clad laminate for chips on film (COFs).

Recently, as the bonding area between a polyimide film and a metal layer is increasingly reduced with further reduction in pitch and linewidth of a microcircuit, stronger adhesion of the polyimide film to the metal layer is required.

Conventionally, in order to promote improvement in adhesion between a polyimide film and a metal plate, a coupling agent capable of providing chemical and/or physical binding between surfaces of the polyimide film and the metal layer has been used. Here, chemical binding may generally refer to an interaction in which some portion of the coupling agent is hydrogen-bonded to some portion of a polymer chain of the polyimide film and the other portion of the coupling agent is hydrogen-bonded to oxygen or the like on the surface of the metal layer.

On the other hand, in order to improve surface binding energy between a polyimide film and a metal layer deposited thereon by sputtering, for example, a copper layer, a metal powder is embedded in the polyimide film to induce improvement in adhesion.

A polyimide film may be prepared from a polyamic acid solution, which is a precursor thereof. Specifically, the polyimide film may be prepared by applying the polyamic acid solution to a support in the form of a thin film, followed by “imidization”, which is a process in which amic acid groups in a polyamic acid are converted into imide groups through ring-closure and dehydration by heat and/or a chemical catalyst.

During imidization, a coupling agent and a metal powder can be physically and/or chemically bound to some portion of a polymer chain of polyimide. For this reason, the coupling agent and the metal powder are used in preparation of polyimide films in the form of a mixture with the polyamic acid solution as a liquid.

However, the coupling agent mixed with the polyamic acid solution is dispersed throughout the solution and thus can remain in a dispersed state upon completion of imidization of the polyamic acid solution. As a result, upon completion of preparation of the polyimide film, most of the coupling agent is present at an inner portion of the film, where the coupling agent will be less likely to interact with the metal layer, and there is a relatively small amount of or no coupling agent on a surface of the film or in a region close thereto, where the coupling agent will be more likely to interact with the metal layer.

In addition, the metal powder mixed with the polyamic acid solution can settle to the bottom of the polyamic acid solution due to high specific gravity thereof. As a result, upon completion of preparation of the polyimide film, most of the metal powder is present at an inner portion of the film, where the metal powder will be less likely to interact with the metal layer, and there is a relatively small amount of or no metal powder on the surface of the film or in a region close thereto, where the metal powder will be more likely to interact with the metal layer, as in the case of the coupling agent.

For these reasons, for a typical polyimide film including a coupling agent and a metal powder, it cannot be ensured that sufficient amounts of the coupling agent and/or the metal powder interact with a surface of a metal layer, making it difficult for the polyimide film to have a desired level of adhesive strength to the metal layer.

Further, the coupling agent and the metal powder present at an inner portion of the polyimide film can cause deterioration in mechanical properties of the polyimide film, such as tensile strength and modulus.

That is, the typical polyimide film can have a secondary problem in that use of the coupling agent and the metal powder only results in slight improvement in adhesive strength at the expense of inherent mechanical properties of polyimide.

Therefore, there is a need for a novel polyimide film which can overcome such problems in the art.

### DISCLOSURE

### Technical Problem

It is one aspect of the present invention to provide a polyimide composite film that can exhibit improved adhesive strength to a metal layer while retaining excellent mechanical properties of polyimide.

A polyimide composite film according to the present invention may include a plurality of polyimide layers, an inorganic powder, and a coupling agent, wherein the inorganic powder and the coupling agent are advantageously used to improve adhesive strength of the polyimide composite film to a metal layer.

The polyimide composite film may be characterized in that most of the inorganic powder and the coupling agent are present in a polyimide layer that forms a surface layer of the composite film. Accordingly, for example, a metal layer formed on an outer polyimide layer of the polyimide composite film by sputtering can interact with the inorganic powder and the coupling agent mostly present in the outer polyimide layer, whereby the polyimide composite film can have excellent adhesive strength to the metal layer at room temperature.

In addition, since the coupling agent and the inorganic powder are concentrated in the surface layer of the composite film, at which the coupling agent and the inorganic powder will be more likely to interact with the metal layer, through use of limited amounts of the coupling agent and the inorganic powder, it is possible to achieve both sufficient adhesive strength of the polyimide composite film and suppression of deterioration in mechanical properties of the film due to the inorganic powder and the coupling agent. If the coupling agent and the inorganic powder are present at an inner portion of the polyimide composite film, mechanical properties of the polyimide film can be greatly deteriorated. However, according to the present invention, structural characteristics of the polyimide composite film as described above can minimize deterioration in mechanical properties of the film.

It is another aspect of the present invention to provide a preparation method suitable for implementation of such a novel polyimide composite film which has the aforementioned advantages.

These aspects have been conceived in order to solve the aforementioned problems in the related art, and the present invention is essentially aimed at providing specific embodiments thereof.

### Technical Solution

In accordance with one aspect of the present invention, there is provided a polyimide composite film including: a first polyimide layer derived from a first polyamic acid solution;

at least one second polyimide layer derived from a second polyamic acid solution and formed on one or both surfaces of the first polyimide layer;

an inorganic powder; and

a coupling agent,

wherein at least 90% of the total weight of the inorganic powder and at least 90% of the total weight of the coupling agent are present in the second polyimide layer, and wherein the polyimide composite film has an adhesive strength of 0.6 kgf/mm² or more, as measured with respect to a metal layer at room temperature, a tensile strength of 0.45 GPa or more, and a modulus of 6 GPa or more.

In accordance with another aspect of the present invention, there is provided a method of preparing the polyimide composite film set forth above.

In accordance with a further aspect of the present invention, there is provided an electronic component including the polyimide composite film set forth above as an insulating film. The electronic component may be a semiconductor device or a flexible circuit board, specifically a flexible circuit board.

The flexible circuit board may include: the polyimide composite film; and a metal layer deposited on a surface of the second polyimide layer of the polyimide composite film by sputtering copper.

It should be understood that terms or words used in this specification and claims have to be interpreted as having a meaning and concept adaptive to the technical idea of the present invention rather than typical or dictionary interpretation on a principle that an inventor is allowed to properly define the concept of the terms in order to explain their own invention in the best way.

Therefore, since embodiments disclosed in this specification are merely preferred examples of the present invention and do not fully describe the technical idea of the present invention, it will be appreciated that there can be various equivalents and alterations thereto at a filing date of the present application.

As used herein, the singular forms “a”, “an” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

As used herein, “dianhydride” is intended to include a precursor or derivative thereof, which may not technically be a dianhydride, but will nevertheless react with diamine to form a polyamic acid, which, in turn, is converted into polyimide.

As used herein, “diamine” is intended to include a precursor or derivative thereof, which may not technically be a diamine, but will nevertheless react with dianhydride to form polyamic acid, which, in turn, is converted into polyimide.

It will be understood that disclosure of a range of values, a preferred range of values, or preferred upper and lower limits for a given parameter, such as amount and concentration, subsumes all possible sub-ranges for the parameter which may be obtained by combining any sets of values within upper and low limits or preferred values as disclosed. Unless indicated otherwise, it is intended that a numerical range recited herein encompass end points thereof, as well as all integers and fractions between the end points. Further, it is intended that the scope of the present invention not be limited to specific values used in defining a range for a certain parameter.

### BRIEF DESCRIPTION OF DRAWINGS

FIG. 1 is a schematic view of a co-extruder.

### MODES OF THE INVENTION

Polyimide Composite Film

A polyimide composite film according to the present invention includes:

a first polyimide layer derived from a first polyamic acid solution;

at least one second polyimide layer derived from a second polyamic acid solution and formed on one or both surfaces of the first polyimide layer;

an inorganic powder; and

a coupling agent,

wherein at least 90% of the total weight of the inorganic powder and at least 90% of the total weight of the coupling agent are present in the second polyimide layer. The polyimide composite film may have an average thickness of 15 to 100 μm, specifically 20 μm to 50 μm, more specifically 25 μm to 40 μm.

In one embodiment, at least 99% of the total weight of the inorganic powder and at least 99% of the total weight of the coupling agent may be present in the second polyimide layer.

That is, the second polyimide layer according to the present invention may refer to a region which is derived from the second polyamic acid solution, contains at least 90%, specifically at least 99%, of the total weight of the inorganic powder and at least 90%, specifically at least 99%, of the total weight of the coupling agent, and forms a surface layer of the polyimide composite film.

The polyimide composite film including the second polyimide layer formed on one or both surfaces of the first polyimide layer may be prepared by co-extrusion of the first polyamic acid solution (or first composition) and the second polyamic acid solution (or second composition) using a multilayer co-extrusion die.

Here, the second polyamic acid solution (or second composition) may include the inorganic powder and the coupling agent, and the first polyamic acid solution (or first composition) may be free from the inorganic powder and the coupling agent.

In some cases, upon co-extrusion of the first polyamic acid solution and the second polyamic acid solution in layers, trace amounts of the first and second polyamic acid solutions can be mixed together at a contact surface between the first and second polyamic acid solutions. Through a subsequent heat treatment process, the mixed part can form an interfacial portion where the first polyimide layer is joined to the second polyimide layer. Since the interfacial portion is extremely thin enough to be unmeasurable, the interfacial portion is not considered as an independent layer and contains substantially little or no coupling agent and inorganic powder.

Here, the first polyimide layer may occupy 60% to 99% of the total volume of the polyimide composite film, and the second polyimide layer may occupy 1% to 40% of the total volume of the polyimide composite film.

In addition, the first polyimide layer may have an average thickness ranging from 60% to 99% of the average thickness of the polyimide composite film, and the second polyimide layer may have an average thickness ranging from 1% to 40% of the average thickness of the polyimide composite film.

Within these ranges of volumes and average thicknesses of the first polyimide layer and the second polyimide layer, the polyimide composite film can have appropriate levels of mechanical properties. In particular, since the first polyimide layer can be most involved in mechanical properties of the polyimide composite film, it is very undesirable that the volume and average thickness of the first polyimide layer be less than the aforementioned ranges. In addition, if the volume and average thickness of the first polyimide layer exceeds the aforementioned ranges, it is difficult for the polyimide composite film to have advantages due to the second polyimide layer, the coupling agent, and the inorganic powder as described below.

The polyimide composite film having this structure has an advantage in that, for example, upon formation of a metal layer on the polyimide composite film by sputtering, the inorganic powder and the coupling agent, which are present in large amounts in the second polyimide layer forming the surface layer of the composite film, interact with the metal layer, thereby allowing binding between the polyimide composite film and the metal layer.

In other words, since the polyimide composite film according to the present invention has a structure in which almost all of the inorganic powder and the coupling agent contained therein are substantially present in the second polyimide layer, a metal layer formed on the second polyimide layer by sputtering, for example, a copper layer, interacts with the coupling agent and the inorganic powder present in large amounts in the second polyimide layer, thereby allowing strong bonding between the polyimide composite film and the metal layer.

Herein, “interaction” may mean, in a broad sense, a process, phenomenon, or form in which the coupling agent and the inorganic powder are physically and/or chemically bound to both a polyimide polymer chain and the metal layer, and may mean, in a narrower sense, a process, phenomenon, or form in which:

(i) some portion of the coupling agent is bound to at least some polar groups of the polyimide polymer chain via hydrogen bonds and the other portion of the coupling agent is bound to oxygen and the like present on a surface of the metal layer via hydrogen bonds;

(ii) some portion of the coupling agent is physically entangled in the polyimide polymer chain and the other portion of the coupling agent is in simple contact with metal particles of the metal layer;

(iii) a metal constituting the metal layer is deposited on the inorganic powder to be physically and chemically bound thereto, with some portion of the coupling agent coupled to both the inorganic powder and the polyimide polymer chain via hydrogen bonds; and/or

(iv) all of (i), (ii), and (iii) are combined.

However, it should be understood that the foregoing is given by way of illustration only and the form in which the polyimide composite film, the coupling agent, and the inorganic powder are bonded to the metal layer is not limited thereto.

Another advantage of the polyimide composite film according to the present invention lies in that the coupling agent and the inorganic powder are concentrated in the second polyimide layer, where the coupling agent and the inorganic powder will be more likely to interact with the metal layer, whereby the polyimide composite film can exhibit a desired level of adhesive strength to the metal layer even though the coupling agent and the inorganic powder are present in somewhat limited amounts based on the total weight of the polyimide composite film.

A typical polyimide film including a coupling agent and an inorganic powder to have improved adhesive strength to a metal layer can have a concentration gradient in which almost all of the coupling agent and the inorganic powder are present at an inner portion of the polyimide film, for example, at a core of the polyimide film, and concentrations of the coupling agent and the inorganic powder are gradually decreased from the core of the film toward the surface of the film. For this reason, such a typical polyimide film is required to contain relatively large amounts of the coupling agent and the inorganic powder in order to have sufficient amounts of the coupling agent and the inorganic powder in a region close to the surface of the film. However, the coupling agent and the inorganic powder can cause deterioration in mechanical properties of the polyimide film. Consequently, improvement in adhesive strength of the typical polyimide to the metal layer is anticipated at the expense of mechanical properties.

Conversely, according to the present invention, almost all of the coupling agent and the inorganic powder used in limited amounts are present in a limited region of the film, specifically, in the second polyimide layer forming the surface layer of the polyimide composite film, and the first polyimide layer containing little or no coupling agent and inorganic powder serves to maintain the overall mechanical strength of the composite film at an appropriate level. Consequently, the polyimide composite film according to the present invention can have appropriate levels of both adhesive strength to the metal layer and various mechanical properties, unlike typical polyimide films in the related art.

Thus, the polyimide composite film according to the present invention may have an adhesive strength of 0.6 kgf/mm² or more, specifically 0.7 kgf/mm² to 1.0 kgf/mm², as measured with respect to the metal layer at room temperature, a tensile strength of 0.45 GPa or more, specifically 0.48 GPa or more, more specifically 0.51 GPa or more, and a modulus of 6 GPa or more, specifically 6.5 GPa or more, more specifically 7.0 GPa or more.

In order to achieve appropriate levels of both adhesive strength and mechanical properties such as tensile strength and modulus, use of appropriate amounts of the inorganic powder and the coupling agent is critical. Accordingly, the present invention specifies the desirable contents of the inorganic powder and the coupling agent.

In one embodiment,

the polyimide composite film may have a structure in which the second polyimide layer is formed on one surface of the first polyimide layer,

wherein the second polyimide layer may include 0.02 wt % to 2 wt %, specifically 0.02 wt % to 1.5 wt %, more specifically 0.05 wt % to 1.3 wt %, still more specifically 0.1 wt % to 1 wt % of the inorganic powder based on the total weight of the polyimide composite film and 200 ppm to 1,000 ppm, specifically 400 ppm to 800 ppm of the coupling agent based on the total weight of the second polyimide layer.

If the content of the inorganic powder in the second polyimide layer is less than this range, effects of the inorganic powder on improvement in adhesive strength of the polyimide composite film to the metal layer can be insignificant, whereas, if the content of the inorganic powder in the second polyimide layer exceeds this range, the polyimide composite film can have poor mechanical properties.

If the content of the coupling agent in the second polyimide layer is less than this range, effects of the coupling agent on improvement in adhesive strength of the polyimide composite film to the metal layer can be insignificant, whereas, if the content of the coupling agent in the second polyimide layer exceeds this range, the polyimide composite film can have poor mechanical properties.

In another embodiment, the polyimide composite film may include a pair of second polyimide layers respectively formed on opposite surfaces of the first polyimide layer,

wherein each of the second polyimide layers may include 200 ppm to 1,000 ppm of the coupling agent based on the total weight thereof and 0.02 wt % to 2 wt % of the inorganic powder based on the total weight of the polyimide composite film.

That is, any one of the second polyimide layers may include 200 ppm to 1,000 ppm, specifically 400 ppm to 800 ppm of the coupling agent based on the total weight thereof and 0.02 wt % to 2 wt %, specifically 0.02 wt % to 1.5 wt %, more specifically 0.05 wt % to 1.3 wt %, still more specifically 0.1 wt % to 1 wt % of the inorganic powder based on the total weight of the polyimide composite film.

Likewise, the other polyimide layer may include 200 ppm to 1,000 ppm, specifically 400 ppm to 800 ppm of the coupling agent based on the total weight thereof and 0.02 wt % to 2 wt %, specifically 0.02 wt % to 1.5 wt %, more specifically 0.05 wt % to 1.3 wt %, still more specifically 0.1 wt % to 1 wt % of the inorganic powder based on the total weight of the polyimide composite film.

The polyimide composite film may include 400 ppm to 2,000 ppm, specifically 800 ppm to 1,600 ppm of the coupling agent based on the total weight of the two second polyimide layers.

If the content of the inorganic powder in each of the second polyimide layers is less than this range, effects of the inorganic powder on improvement in adhesive strength of the polyimide composite film to the metal layer can be insignificant, whereas, if the content of the inorganic powder in each of the second polyimide layers exceeds this range, the polyimide composite film can have poor mechanical properties.

If the content of the coupling agent in each of the second polyimide layers is less than this range, effects of the coupling agent on improvement in adhesive strength of the polyimide composite film to the metal layer can be insignificant, whereas, if the content of the coupling agent in each of the second polyimide layers exceeds this range, the polyimide composite film can have poor mechanical properties.

In the present invention, the inorganic powder may be a metal powder, and may include at least one metal powder selected from the group consisting of nickel, chromium, iron, aluminum, copper, titanium, silver, gold, cobalt, manganese, zirconium, and alloys thereof, without being limited thereto.

The inorganic powder may have an average particle diameter (D50) of 0.1 μm to 2 μm.

If the average particle diameter of the inorganic powder is less than this range, effects of the inorganic powder on improvement in adhesive strength of the polyimide composite film to the metal layer can be insignificant.

If the average particle diameter of the inorganic powder exceeds this range, the inorganic powder is likely to stick out of the surface of the second polyimide layer, causing surface defects such as protrusions and pinholes. In addition, the inorganic powder having a relatively large average particle diameter is likely to agglomerate together on the surface of the second polyimide layer and to act as foreign matter inhibiting adhesive strength of the polyimide composite film.

The coupling agent may include at least one selected from the group consisting of a titanate coupling agent, an organic chrome complex coupling agent, a silane coupling agent, and an aluminate coupling agent. Specifically, the coupling agent may include at least one selected from the group consisting of 1H,1H,2H,2H-perfluorooctyltriethoxysilane, 1H, 1H,2H,2H-perfluorodecyltrimethoxysilane, 1H, 1H,2H,2H-heptadecafluorodecyltrisisopropoxysilane, 1H, 1H,2H,2H-perfluorooctyltrimethoxysilane, trimethoxy(3,3-trifluoropropyl) silane, dodecafluoroheptylpropyl methyl dimethoxysilane, dodecafluoroheptylpropyltrimethoxysilane, trimethyl(trifluoromethyl)silane, γ-glycidoxypropyltrimethoxysilane, 3-glycidoxypropylmethyldiethoxysilane, 3-glycidoxypropylmethyldimethoxysilane, 3-glycidoxypropyltriethoxysilane, 2-(3,4-epoxycyclohexyl)ethyltrimethoxysilane, 2-(3,4-epoxycyclohexyl)ethylmethyldimethoxysilane, 2-(3,4-epoxycyclohexyl)ethylmethyldiethoxysilane, 2-(3,4-epoxycyclohexyl)ethyltriethoxysilane, 5,6-epoxyhexyltrimethoxysilane, 5,6-epoxyhexylmethyldimethoxysilane, 5,6-epoxyhexylmethyldiethoxysilane, 5,6-epoxyhexyltriethoxysilane, 3-mercaptopropylmethyldimethoxysilane, 3-mercaptopropyltrimethoxysilane, 3-mercaptopropylmethyldiethoxysilane, 3-mercaptopropyltriethoxysilane, 3-trimethoxysilylpropyl succinic anhydride, 3-triethoxysilylpropyl succinic anhydride, oligomerized alkoxy oligomer, N-2(aminoethyl)3-aminopropylmethyldimethoxysilane, N-2(aminoethyl)3-aminopropyltrimethoxysilane, N-2(aminoethyl)3-aminopropyltriethoxysilane, 3-(2-aminoethylamino)propyl-dimethoxymethylsilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, N-(vinylbenzyl)-2-aminoethyl-3-aminopropyltrimethoxysilane hydrochloride, 3-aminopropylmethyldiethoxysilane, 3-aminopropyl-tris(2-methoxy-ethoxy-ethoxy)silane, N-methyl-3-aminopropyltrimethoxysilane, and triaminopropyl-trimethoxysilane.

In one embodiment, the first polyamic acid solution and the second polyamic acid solution may be prepared using the same monomer combination, wherein the monomer combination may include at least one dianhydride monomer and at least one diamine monomer.

A polyamic acid in the precursor composition may be prepared by polymerization of at least one diamine monomer and at least one dianhydride monomer in an organic solvent.

The diamine monomer is an aromatic diamine, and may be classified as follows:

1) a relatively rigid diamine having one benzene ring, such as 1,4-diaminobenzene (or paraphenylenediamine, PDA, PPD), 1,3-diaminobenzene, 2,4-diaminotoluene, 2,6-diaminotoluene, 3,5-diaminobenzoic acid (or DABA);

2) a diamine having two benzene rings, such as diaminodiphenyl ethers including 4,4′-diaminodiphenyl ether (or oxydianiline, ODA) and 3,4′-diaminodiphenyl ether, 4,4′-diaminodiphenylmethane (or 4,4′-methylenediamine, MDA), 3,3′-dimethyl-4,4′-diaminobiphenyl, 2,2′-dimethyl-4,4′-diaminobiphenyl, 2,2′-bis(trifluoromethyl)-4,4′-diaminobiphenyl, 3,3′-dimethyl-4,4′-diaminodiphenylmethane, 3,3′-dicarboxy-4,4′-diaminodiphenylmethane, 3,3%5,5′-tetramethyl-4,4′-diaminodiphenylmethane, bis(4-aminophenyl)sulfide, 4,4′-diaminobenzanilide, 3,3′-dimethylbenzidine (or o-tolidine), 2,2′-dimethylbenzidine (or m-tolidine), 3,3′-dimethoxybenzidine, 2,2′-dimethoxybenzidine, 3,3′-diaminodiphenyl ether, 3,4′-diaminodiphenyl ether, 4,4′-diaminodiphenyl ether, 3,3′-diaminodiphenyl sulfide, 3,4′-diaminodiphenyl sulfide, 4,4′-diaminodiphenyl sulfide, 3,3′-diaminodiphenyl sulfone, 3,4′-diaminodiphenyl sulfone, 4,4′-diaminodiphenyl sulfone, 3,3′-diaminobenzophenone, 4,4′-diaminobenzophenone, 3,3′-diamino-4,4′-dichlorobenzophenone, 3,3′-diamino-4,4′-dimethoxybenzophenone, 3,3′-diaminodiphenylmethane, 3,4′-diaminodiphenylmethane, 4,4′-diaminodiphenylmethane, 2,2-bis(3-aminophenyl)propane, 2,2-bis(4-aminophenyl)propane, 2,2-bis(3-aminophenyl)-1, 1,1,3,3,3-hexafluoropropane, 2,2-bis(4-aminophenyl)-1, 1,1,3,3,3-hexafluoropropane, 3,3′-diaminodiphenyl sulfoxide, 3,4′-diaminodiphenyl sulfoxide, and 4,4′-diaminodiphenyl sulfoxide;

3) a diamine having three benzene rings, such as 1,3-bis(3-aminophenyl)benzene, 1,3-bis(4-aminophenyl)benzene, 1,4-bis(3-aminophenyl)benzene, 1,4-bis(4-amino phenyl)benzene, 1,3-bis(4-aminophenoxy)benzene (or TPE-R), 1,4-bis(3-aminophenoxy)benzene (or TPE-Q), 1,3-bis(3-aminophenoxy)-4-trifluoromethylbenzene, 3,3′-diamino-4-(4-phenyl)phenoxybenzophenone, 3,3′-diamino-4,4′-di(4-phenylphenoxy)benzophenone, 1,3-bis(3-aminophenylsulfide)benzene, 1,3-bis(4-aminophenylsulfide)benzene, 1,4-bis(4-aminophenylsulfide)benzene, 1,3-bis(3-aminophenylsulfone)benzene, 1,3-bis(4-aminophenylsulfone)benzene, 1,4-bis(4-aminophenylsulfone)benzene, 1,3-bis[2-(4-aminophenyl)isopropyl]benzene, 1,4-bis[2-(3-aminophenyl)isopropyl]benzene, and 1,4-bis[2-(4-aminophenyl)isopropyl]benzene; and

4) a diamine having four benzene rings, such as 3,3′-bis(3-aminophenoxy)biphenyl, 3,3′-bis(4-aminophenoxy)biphenyl, 4,4′-bis(3-aminophenoxy)biphenyl, 4,4′-bis(4-aminophenoxy)biphenyl, bis[3-(3-aminophenoxy)phenyl]ether, bis[3-(4-aminophenoxy)phenyl]ether, bis[4-(3-aminophenoxy)phenyl]ether, bis[4-(4-aminophenoxy)phenyl]ether, bis[3-(3-aminophenoxy)phenyl]ketone, bis[3-(4-aminophenoxy)phenyl]ketone, bis[4-(3-aminophenoxy)phenyl]ketone, bis[4-(4-aminophenoxy)phenyl]ketone, bis[3-(3-aminophenoxy)phenyl]sulfide, bis[3-(4-aminophenoxy)phenyl]sulfide, bis[4-(3-aminophenoxy)phenyl]sulfide, bis[4-(4-aminophenoxy)phenyl]sulfide, bis[3-(3-aminophenoxy)phenyl]sulfone, bis[3-(4-aminophenoxy)phenyl]sulfone, bis[4-(3-aminophenoxy)phenyl]sulfone, bis[4-(4-aminophenoxy)phenyl]sulfone, bis[3-(3-aminophenoxy)phenyl]methane, bis[3-(4-aminophenoxy)phenyl]methane, bis[4-(3-aminophenoxy)phenyl]methane, bis[4-(4-aminophenoxy)phenyl]methane, 2,2-bis[3-(3-aminophenoxy)phenyl]propane, 2,2-bis[3-(4-aminophenoxy)phenyl]propane, 2,2-bis[4-(3-aminophenoxy)phenyl]propane, 2,2-bis[4-(4-aminophenoxy)phenyl]propane (BAPP), 2,2-bis[3-(3-aminophenoxy)phenyl]-1, 1,1,3,3,3-hexafluoropropane, 2,2-bis[3-(4-aminophenoxy)phenyl]-1, 1,1,3,3,3-hexafluoropropane, 2,2-bis[4-(3-aminophenoxy)phenyl]-1, 1,1,3,3,3-hexafluoropropane, and 2,2-bis[4-(4-aminophenoxy)phenyl]-1, 1,1,3,3,3-hexafluoropropane.

These may be used alone or in combination thereof, as desired.

The dianhydride monomer may be an aromatic tetracarboxylic dianhydride.

Examples of the aromatic tetracarboxylic dianhydride may include pyromellitic dianhydride (or PMDA), 3,3′,4,4′-biphenyltetracarboxylic dianhydride (or s-BPDA), 2,3,3′,4′-biphenyltetracarboxylic dianhydride (or a-BPDA), oxydiphthalic dianhydride (or ODPA), diphenylsulfone-3,4,3′,4′-tetracarboxylic dianhydride (or DSDA), bis(3,4-dicarboxyphenyl)sulfide dianhydride, 2,2-bis(3,4-dicarboxyphenyl)-1,1,1,3,3,3-hexafluoropropane dianhydride, 2,3,3′,4′-benzophenonetetracarboxylic dianhydride, 3,3′,4,4′-benzophenonetetracarboxylic dianhydride (or BTDA), bis(3,4-dicarboxyphenyl)methane dianhydride, 2,2-bis(3,4-dicarboxyphenyl)propane dianhydride, p-phenylenebis(trimellitic monoester acid anhydride), p-biphenylenebis(trimellitic monoester acid anhydride), m-terphenyl-3,4,3′,4′-tetracarboxylic dianhydride, p-terphenyl-3,4,3′,4′-tetracarboxylic dianhydride, 1,3-bis(3,4-dicarboxyphenoxy)benzene dianhydride, 1,4-bis(3,4-dicarboxyphenoxy)benzene dianhydride, 1,4-bis(3,4-dicarboxyphenoxy)biphenyl dianhydride, 2,2-bis[(3,4-dicarboxyphenoxy)phenyl]propane dianhydride (BPADA), 2,3,6,7-naphthalenetetracarboxylic acid dianhydride, 1,4,5,8-naphthalenetetracarboxylic dianhydride, and 4,4′-(2,2-hexafluoroisopropylidene)diphthalic acid dianhydride. These may be used alone or in combination thereof, as desired.

In one embodiment, the dianhydride monomer may include pyromellitic dianhydride (PMDA) and may further include 3,3′,4,4′-biphenyltetracarboxylic dianhydride (s-BPDA) or 2,3,3′,4′-biphenyltetracarboxylic dianhydride (a-BPDA), and

the diamine monomer may include 1,4-diaminobenzene (paraphenylene diamine, PDA, PPD) and 4,4′-diaminodiphenyl ether (oxydianiline, ODA).

In another embodiment, the first polyamic acid solution and the second polyamic acid solution may be prepared using different monomer combinations, wherein each of the monomer combinations may include at least one dianhydride monomer and at least one diamine monomer.

A polyamic acid in the precursor composition may be prepared by polymerization of at least one diamine monomer and at least one dianhydride monomer in an organic solvent.

In a further embodiment, the first polyamic acid solution and the second polyamic acid solution may be prepared using different monomer combinations, wherein the second polyamic acid may be prepared by polymerization of a first dianhydride, a second dianhydride, a first diamine, and a second diamine.

Here, the first dianhydride may include at least one selected from the group consisting of 3,3′,4,4′-biphenyltetracarboxylic dianhydride (s-BPDA) and 2,3,3′,4′-biphenyltetracarboxylic dianhydride (a-BPDA);

the first diamine may include at least one selected from the group consisting of paraphenylenediamine (PPD) and metaphenylenediamine (MPD);

the second dianhydride may include at least one dianhydride different from the first dianhydride; and

the second diamine may include at least one diamine different from the first diamine.

The second dianhydride may include at least one selected from the group consisting of pyromellitic dianhydride (PMDA), oxydiphthalic dianhydride (ODPA), diphenylsulfone-3,4,3′,4′-tetracarboxylic dianhydride (DSDA), 3,3′,4,4′-benzophenonetetracarboxylic dianhydride (or BTDA) and 2,2-bis[(3,4-dicarboxyphenoxy)phenyl]propane dianhydride (BPADA), and the second diamine may include at least one selected from the group consisting of 4,4′-diaminodiphenyl ether (oxydianiline, ODA) and 3,4′-diaminodiphenyl ether.

In one embodiment, the first dianhydride, the second dianhydride, the first diamine, and the second diamine may be 3,3′,4,4′-biphenyltetracarboxylic dianhydride, pyromellitic dianhydride, paraphenylenediamine, and 4,4′-diaminodiphenyl ether, respectively.

The first dianhydride may be present in an amount of 40 mol % to 50 mol % based on the total number of moles of the first dianhydride and the second dianhydride, the second dianhydride may be present in an amount of 50 mol % to 60 mol % based on the total number of moles of the first dianhydride and the second dianhydride, the first diamine may be present in an amount of 80 mol % to 92 mol % based on the total number of moles of the first diamine and the second diamine, and the second diamine may be present in an amount of 8 mol % to 20 mol % based on the total number of moles of the first diamine and the second diamine.

When the first polyamic acid solution and the second polyamic acid solution are prepared from different monomer mixtures as described above, the polyimide composite film prepared therefrom has a coefficient of thermal expansion of 2 μm/m·° C. to 7 μm/m·° C. and a glass transition temperature of 370° C. or higher.

Method of Preparing Polyimide Composite Film

A method of preparing a polyimide composite film may include: preparing a first composition including a first polyamic acid solution and a second composition including a second polyamic acid solution, an inorganic powder, and a coupling agent;

supplying the first and second compositions to a multilayer co-extrusion die and co-extruding the first and second compositions using the co-extrusion die such that the first composition and the second composition are stacked one above another; and

imidizing the co-extruded first and second compositions. Although an organic solvent used in the method may include any organic solvent capable of dissolving a polyamic acid, without limitation, the organic solvent may be, for example, an aprotic polar solvent.

Examples of the aprotic polar solvent may include amide solvents, such as N,N′-dimethylformamide (DMF) and N,N′-dimethylacetamide (DMAC), phenol solvents, such as p-chlorophenol and o-chlorophenol, N-methyl-pyrrolidone (NMP), gamma-butyrolactone (GBL), and diglyme. These may be used alone or in combination thereof.

An auxiliary solvent, such as toluene, tetrahydrofuran, acetone, methyl ethyl ketone, methanol, ethanol, and water, may be used to adjust solubility of a polyamic acid, as needed.

In one embodiment, the organic solvent used in preparation of the first and second polyamic acid solutions preferably includes N,N′-dimethylformamide and N, N′-dimethylacetamide, which are amide solvents.

Each of the first and second polyamic acid solutions may be prepared as follows:

(1) by mixing all diamine monomer components with an organic solvent and adding all dianhydride monomer components such that the total amount of all of the diamine monomer components is substantially equimolar to the total amount of all of the dianhydride monomer components, followed by polymerization;

(2) by mixing all dianhydride monomer components with an organic solvent and adding all diamine monomer components such that the total amount of all of the diamine monomer components is substantially equimolar to the total amount of all of the dianhydride monomer components, followed by polymerization;

(3) by mixing some diamine monomer components with an organic solvent, adding some dianhydride monomer components in an amount of 95% to 105% of the number of moles of the introduced reactants, and sequentially adding the other diamine monomer components and the other dianhydride monomer components such that the total amount of all of the diamine monomer components is substantially equimolar to the total amount of all of the dianhydride monomer components, followed by polymerization;

(4) by mixing some dianhydride monomer components with an organic solvent, adding some diamine monomer components in an amount of 95% to 105% of the number of moles of the introduced reactants, and sequentially adding the other dianhydride monomer components and the other diamine monomer components such that the total amount of all of the diamine monomer components is substantially equimolar to the total amount of the dianhydride monomer components, followed by polymerization; or

(5) by mixing some diamine monomer components and some dianhydride monomer components with an organic solvent such that the total amount of the diamine monomer components is larger or smaller than that of the dianhydride monomer components, followed by reaction to form a first polymerization product; mixing the other diamine monomer components and the other dianhydride monomer components with another organic solvent such that the total amount of the diamine monomer components is larger or smaller than that of the dianhydride monomer components, followed by reaction to form a second polymerization product; and mixing the first polymerization product with the second polymerization product, followed by polymerization of the mixture, wherein, if the total amount of the diamine monomer components used in formation of the first polymerization product is larger than that of the dianhydride monomer components used in formation of the first polymerization product, the total amount of the diamine monomer components used in formation of the second polymerization product is smaller than that of the dianhydride monomer components used in formation of the second polymerization product, and, if the total amount of the diamine monomer components used in formation of the first polymerization product is smaller than that of the dianhydride monomer components used in formation of the first polymerization product, the total amount of the diamine monomer components used in formation of the second polymerization product is larger than that of the dianhydride monomer components used in formation of the second polymerization product such that the total amount of all of the diamine monomer components used in polymerization is substantially equimolar to the total amount of all of the dianhydride monomer components used in polymerization.

However, it should be understood that these methods are given by way of illustration only and the present invention is not limited thereto. Therefore, the first polyamic acid solution and the second polyamic acid solution may be prepared by any suitable method known in the art.

A polyamic acid included in each of the first polyamic acid solution and the second polyamic acid solution may have a weight average molecular weight of 150,000 g/mol to 1,000,000 g/mol, specifically 260,000 g/mol to 700,000 g/mol, more specifically 280,000 g/mol to 500,000 g/mol.

Within this range of weight average molecular weight of the polyamic acid, the polyimide composite film can have further improved heat resistance and mechanical properties.

In general, the weight average molecular weight of the polyamic acid is proportional to viscosity of a polyamic acid solution including the polyamic acid and an organic solvent. Accordingly, it is possible to control the weight average molecular weight of the polyamic acid to fall within the aforementioned range by adjusting the viscosity of the polyamic acid solution.

This is because the viscosity of the polyamic acid solution is proportional to the content of the solid polyamic acid, specifically to the total amount of the dianhydride and diamine monomers used in polymerization. However, the weight average molecular weight of the polyamic acid is logarithmically proportional to viscosity of the polyamic acid solution rather than linearly proportional to the viscosity.

That is, increase in viscosity of the polyamic acid solution can only increase the weight average molecular weight of the polyamic acid to a limited extent. Further, upon discharging the polyamic acid solution through the multilayer die in a film forming process through co-extrusion, excessively high viscosity of the polyamic acid solution can cause a problem of deterioration in processability due to increase in internal pressure of the multilayer die.

Accordingly, each of the first and second polyamic acid solutions may include 15 wt % to 20 wt % of the polyamic acid (in terms of solid content) and 80 wt % to 85 wt % of the organic solvent. In this case, the viscosity of each of the first and second polyamic acid solutions may range from 90,000 cP to 150,000 cP, specifically 100,000 cP to 130,000 cP. Within this range of viscosity, the weight average molecular weight of the polyamic acid can fall within the aforementioned range and the polyamic acid solutions can avoid the film forming process-related problem described above.

In preparation of each of the first and second compositions, fillers may be added to improve various properties of the polyimide composite film, such as slidability, thermal conductivity, electrical conductivity, corona resistance, and loop hardness. Although the type of fillers used is not particularly restricted, preferred examples thereof may include silica, titanium oxide, alumina, silicon nitride, boron nitride, calcium hydrogen phosphate, calcium phosphate, and mica.

The average particle diameter of the fillers is not particularly restricted and may be varied depending on properties of the polyimide composite film to be modified and the type of fillers added. In one embodiment, the fillers may have an average particle diameter of 0.05 μm to 2.5 μm, specifically 0.1 μm to 2 μm, more specifically 0.1 μm to 2 μm, still more specifically 0.1 μm to 2 μm.

If the average particle diameter of the fillers is less than this range, the fillers can be less effective in modifying properties of the polyimide composite film, whereas, if the average particle diameter of the fillers exceeds this range, the fillers can cause significant deterioration in surface characteristics of the polyimide composite film or can cause deterioration in mechanical properties of the polyimide composite film.

The amount of the fillers is not particularly limited and may be varied depending on properties of the polyimide film to be modified and the particle diameter of the fillers.

In one embodiment, the fillers may be present in an amount of 0.01 parts by weight to 100 parts by weight, specifically 0.01 parts by weight to 90 parts by weight, more specifically 0.02 parts by weight to 80 parts by weight, relative to 100 parts by weight of the polyamic acid solution.

If the amount of the fillers is less than this range, the fillers can be less effective in modifying properties of the polyimide film, whereas, if the amount of the fillers exceeds this range, the polyimide film can have significantly poor mechanical properties. It will be understood that a method of adding the fillers is not particularly restricted and addition of the fillers may be performed by any suitable method known in the art.

In one embodiment, co-extruding the first and second compositions may include co-extruding the first and second compositions onto a support such that the second composition, the first composition, and the second composition are sequentially stacked on the support and performing primary heat treatment of the co-extruded first and second compositions at a temperature of 50° C. to 200° C., and

imidizing the co-extruded first and second compositions may include performing secondary heat treatment of the first and second compositions subjected to primary heat treatment at a temperature of 200° C. to 700° C.,

wherein the polyimide composite film may have a structure in which a second polyimide layer derived from the second composition is formed on both surfaces of a first polyimide layer derived from the first composition.

That is, the polyimide composite film prepared as described above may have a structure in which the second polyimide layer A, the first polyimide layer B, and the second polyimide layer A are stacked in the stated order, as viewed upward from the ground, and are all integrally bonded to one another. In the structure of the composite film, abbreviated as “ABA”, an interfacial portion derived from a mixed solution including trace amounts of the first and second polyamic acid solutions may be present between A and B.

In another embodiment,

co-extruding the first and second compositions may include co-extruding the first and second compositions onto a support such that the second composition and the first composition are sequentially stacked on the support and performing primary heat treatment of the first and second compositions at a temperature of 50° C. to 200° C., and

imidizing the co-extruded first and second compositions may include performing secondary heat treatment of the first and second compositions subjected to the primary heat treatment at a temperature of 200° C. to 700° C.,

wherein the polyimide composite film may have a structure in which a second polyimide layer derived from the second composition is formed on one surface of a first polyimide layer derived from the first composition.

That is, the polyimide composite film prepared as described above may have a structure in which the second polyimide layer A and the first polyimide layer B are stacked in the stated order, as viewed upward from the ground, and are all integrally bonded to one another.

However, it should be understood that, in this structure, spatial location of the layer “A” is not limited to “below,” “at a lower side of,” “at the top of,” and the like and the layer A may be construed as located “above,” “at an upper side,” “at the bottom of,” and the like. In the structure of the composite film, abbreviated as “AB”, an interfacial portion derived from a mixed solution including trace amounts of the first and second polyamic acid solutions may be present between A and B.

In each heat treatment process, in the course of conversion of the second polyamic acid solution in the second composition into a polyimide resin through ring closure and dehydration, the inorganic powder and the coupling agent may interact with the polyimide resin to be bound thereto.

In this regard, ring closure and dehydration in each heat treatment process may refer to imidization of the first polyamic acid solution and the second polyamic acid solution.

Herein, “imidization” refers to a phenomenon, process, or method in which ring closure and dehydration of amic acid groups constituting the polyamic acid are induced by heat and/or a catalyst, whereby the amic acid groups are converted into imide groups.

Here, the imidization may be carried out by a thermal imidization method, a chemical imidization method, or a combined imidization method using a combination of thermal imidization and chemical imidization. Next, these methods will be described using the following non-limiting examples:

<Thermal Imidization Method>

The thermal imidization method is a method of inducing imidization using a heat source such as a hot air dryer or an infrared dryer without any chemical catalyst, and may include:

forming a gel film having at least two layers each derived from the first composition or the second composition through heat treatment of the first and second compositions at a relatively low temperature; and

obtaining a polyimide composite film through heat treatment of the gel film at a relatively high temperature.

Herein, the “gel film” may be understood as a self-supported film intermediate which is formed in an intermediate stage of conversion of the polyamic acid into polyimide.

Forming the gel film may include co-extruding the first composition and at least one second composition onto a support, such as a glass plate, aluminum foil, an endless stainless belt, or a stainless drum, followed by drying of the co-extruded first composition and at least one second composition on the support at a variable temperature of 50° C. to 200° C., specifically 80° C. to 150° C.

In this way, the first composition and the at least one second composition are partially cured and/or dried, thereby forming the gel film having at least two layers each derived from the first composition or the at least one second composition. Thereafter, the gel film is peel off of the support, thereby obtaining the gel film.

As needed, a process of stretching the gel film may be performed in order to adjust the thickness and size of the polyimide composite film obtained by subsequent heat treatment and to improve orientation of the polyimide composite film, wherein stretching of the gel film may be performed in at least one of a machine direction MD and a transverse direction TD with respect to the machine direction.

Then, the resulting gel film may be secured to a tenter and subjected to heat treatment at a variable temperature of 50° C. to 750° C., specifically 150° C. to 700° C., to remove water and solvent residues from the gel film and to imidize almost all remaining amic acid groups, thereby obtaining the polyimide composite film according to the present invention.

As needed, the obtained polyimide composite film may be subjected to heat-finishing treatment at a temperature of 400° C. to 650° C. for 5 to 400 seconds to be further cured. Here, this treatment may be performed under a predetermined tension to relieve any remaining stress from the obtained polyimide film.

<Chemical Imidization Method>

The chemical imidization method is a method of promoting imidization of amic acid groups by adding a dehydrating agent and/or an imidizing agent to each of the first and second compositions.

Herein, the “dehydrating agent” refers to a substance that promotes ring closure of the polyamic acid through dehydration of the polyamic acid, and examples thereof may include aliphatic acid anhydrides, aromatic acid anhydrides, N, N′-dialkylcarbodiimide, halogenated lower aliphatic acid anhydrides, halogenated lower fatty acid anhydrides, aryl phosphonic dihalides, and thionyl halides.

Thereamong, the aliphatic acid anhydrides are preferred in view of ease of availability and cost, and examples thereof may include acetic anhydride (AA), propionic acid anhydride, and lactic acid anhydride. These may be used alone or as a mixture thereof.

In addition, the “imidizing agent” refers to a substance that promotes ring closure of the polyamic acid, and examples thereof may include amine compounds such as aliphatic tertiary amines, aromatic tertiary amines, and heterocyclic tertiary amines. Thereamong, the heterocyclic tertiary amines are preferred in view of catalytic reactivity. Examples of the heterocyclic tertiary amines may include quinoline, isoquinoline, β-picoline (BP), and pyridine. These may be used alone or as a mixture thereof.

In each of the first and second compositions, the dehydrating agent may be present in an amount of 0.5 moles to 5 moles, specifically 1.0 mole to 4 moles, per mole of amic acid groups of the polyamic acid included in each composition. In addition, in each of the first and second compositions, the imidizing agent may be present in an amount of 0.05 moles to 2 moles, specifically 0.2 moles to 1 mole, per mole of amic acid groups of the polyamic acid included in each composition.

If the amounts of the dehydrating agent and the imidizing agent are less than the aforementioned respective ranges, the prepared polyimide composite film can suffer from cracking and deterioration in mechanical strength due to insufficient chemical imidization. If the amounts of the dehydrating agent and the imidizing agent exceed the aforementioned respective ranges, difficulty in casting into multilayer film form or brittleness of the prepared polyimide composite film can be caused by excessively rapid imidization.

<Combined Imidization Method>

The combined imidization method in which thermal imidization is further performed in conjunction with chemical imidization as described above may be employed in preparation of the polyimide composite film.

Specifically, the combined imidization method may include: a chemical imidization process in which a dehydrating agent and/or an imidizing agent are added to each of the first and second compositions at a relatively low temperature; and a thermal imidization process in which the first and second compositions are dried to form a gel film, followed by heat treatment of the gel film.

Upon performing the chemical imidization process, the types and amounts of dehydrating agent and imidizing agent used may be appropriately selected as described in the chemical imidization method.

In the gel film forming process, the first and second compositions each including the dehydrating agent and/or the imidizing agent are co-extruded in film form on a support, such as a glass plate, aluminum foil, an endless stainless belt, or a stainless drum, followed by drying of the co-extruded first and second compositions on the support at a variable temperature of 50° C. to 180° C., specifically 80° C. to 180° C. In this process, the dehydrating agent and/or the imidizing agent may act as a catalyst to promote conversion of amic acid groups into imide groups.

As needed, a process of stretching the gel film may be performed in order to adjust the thickness and size of a polyimide composite film obtained by subsequent heat treatment and to improve orientation of the polyimide composite film, wherein stretching of the gel film may be performed in at least one of a machine direction MD and a transverse direction TD with respect to the machine direction.

Then, the resulting gel film may be secured to a tenter and subjected to heat treatment at a variable temperature of 50° C. to 500° C., specifically 150° C. to 300° C., to remove water, catalyst, and solvent residues from the gel film and to imidize almost all remaining amic acid groups, thereby obtaining the polyimide composite film according to the present invention. In this heat treatment process, the dehydrating agent and/or the imidizing agent may also act as a catalyst to promote conversion of amic acid groups into imide groups, thereby allowing a high imidization rate.

As needed, the obtained polyimide composite film may be subjected to heat-finishing treatment at a temperature of 400° C. to 700° C. for 5 to 400 seconds to be further cured. Here, this treatment may be performed under a predetermined tension to relieve any remaining stress from the obtained polyimide film, as needed.

Next, the present invention will be described in more detail with reference to examples. However, it should be noted that these examples are provided for illustration only and should not be construed in any way as limiting the invention.

### Preparative Example 1-1: Preparation of First Composition

830 g of DMF as a solvent was introduced into a 1 L reactor at 25° C. under a nitrogen atmosphere, and then 41 g of PMDA, 59 g of BPDA, 38 g of PPD, and 10 g of ODA were added, followed by polymerization, thereby preparing a first composition including a first polyamic acid solution (solid first polyamic acid: 149 g).

### Preparative Example 1-2: Preparation of First Composition

DMF as a solvent was introduced into a 1 L reactor at 10° C. under a nitrogen atmosphere, and then s-BPDA as a first dianhydride and PPD as a first diamine were added, followed by polymerization. Thereafter, a first PMDA as a second dianhydride and ODA as a second diamine were added, followed by polymerization while stirring for 1 hour. Thereafter, a second PMDA as a second dianhydride was added to allow the total number of moles of the first and second dianhydrides to be substantially equal to that of the first and second diamines, followed by stirring for 1 hour, thereby preparing a first composition including a final polyamic acid solution. The molar ratio between the used dianhydride monomers and diamine monomers were as shown in Table 1.

TABLE 1

| Dianhydride monomer (mol %) | | | Diamine monomer (mol %) | |
|---|---|---|---|---|
| First | Second dianhydride | | First | Second |
| dianhydride | First | Second | diamine | diamine |
| (s-BPDA) | PMDA | PMDA | (PPD) | (ODA) |
| 50 | 49 | 1 | 92 | 8 |

### Preparative Example 2: Preparation of Second Composition

848 g of DMF as a solvent was introduced into a 1 L reactor at 25° C. under a nitrogen atmosphere, and then 45 g of PMDA, 60 g of BPDA, 41 g of PPD, and 6.5 g of ODA were added, followed by polymerization, thereby preparing a second polyamic acid solution (solid second polyamic acid: 152 g).

Thereafter, a mixture of 251 g of DMF, 103 g of isoquinoline, 245 g of acetic anhydride, 200 mg of nickel as an inorganic powder, and 200 mg (200 ppm) of a coupling agent was added to the second polyamic acid solution, followed by stirring, thereby preparing a second composition.

### Example 1

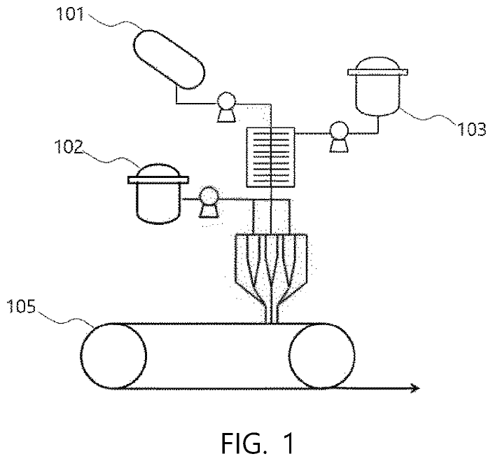

The first composition prepared in Preparation Example 1-1 was introduced into a first reservoir 101 of a co-extrusion die 100 as shown in FIG. 1, and the second composition prepared in Preparation Example 2 was introduced into a second reservoir 102.

Thereafter, the first and second compositions were co-extruded onto an endless belt 105 such that the second composition (thickness: 2.5 μm), the first composition (thickness: 30 μm), and the second composition (thickness: 2.5 μm) were sequentially stacked on the endless belt, thereby forming a film having a thickness of about 35 μm.

Here, upon extrusion of the first composition from the first reservoir 101, isoquinoline, dimethylformamide and acetic anhydride from a catalyst reservoir 103 were mixed with the first composition.

Thereafter, the resulting co-extrusion product was subjected to heat treatment at a temperature of about 150° C. and then heated from 200° C. to 600° C. in a hot tenter, followed by cooling to 25° C., thereby obtaining a polyimide composite film having a multilayer structure (second polyimide layer/first polyimide layer/second polyimide layer).

The amounts of the solid first polyamic acid, the solid second polyamic acid, the coupling agent, and the inorganic powder are shown in Table 2.

### Example 2

A polyimide composite film was prepared in the same manner as in Example 1 except that the second composition was prepared by changing the amount of the coupling agent such that each of the second polyimide layers contained 400 ppm of the coupling agent.

### Example 3

A polyimide composite film was prepared in the same manner as in Example 1 except that the second composition was prepared by changing the amount of the coupling agent such that each of the second polyimide layers contained 1,000 ppm of the coupling agent.

### Example 4

A polyimide composite film was prepared in the same manner as in Example 2 except that the first composition prepared in Preparation Example 1-2 was introduced into the first reservoir 101.

### Comparative Example 1

A polyimide composite film was prepared in the same manner as in Example 1 except that use of the coupling agent in the second composition was omitted.

### Comparative Example 2

A polyimide composite film was prepared in the same manner as in Example 1 except that the second composition was prepared by changing the amount of the coupling agent such that each of the second polyimide layers contained 100 ppm of the coupling agent.

### Comparative Example 3

A polyimide composite film was prepared in the same manner as in Example 1 except that, in Preparative Example 2, the amount of nickel was changed to be 0.01% of the total weight of the polyimide composite film.

### Comparative Example 4

A polyimide composite film was prepared in the same manner as in Example 1 except that, in Preparative Example 2, the amount of nickel was changed to be 6% of the total weight of the polyimide composite film.

The amount (based on the weight of each second polyimide layer) of the coupling agent used in Examples 1 to 4 and Comparative Examples 1 to 4, and the amount (based on the total weight of the polyimide composite film) of the inorganic powder used in Examples 1 to 4 and Comparative Examples 1 to 4 are shown in Table 2.

TABLE 2

| | Amount of | Amount of |
|---|---|---|
| | coupling agent* | inorganic powder** |
| | (ppm) | (wt %) |
| Example 1 | 200 | 0.02 |
| Example 2 | 400 | 0.02 |
| Example 3 | 1000 | 0.02 |
| Example 4 | 400 | 0.02 |
| Comparative | 0 | 0.02 |
| Example 1 | | |
| Comparative | 100 | 0.02 |
| Example 2 | | |
| Comparative | 200 | 0 |
| Example 3 | | |
| Comparative | 200 | 6 |
| Example 4 | | |

*Amount (unit: ppm) of the coupling agent in each second polyimide layer
**Amount (unit: wt %) of the inorganic powder in the polyimide composite film

### Experimental Example: Evaluation of Properties of Polyimide Composite Film

For each of the polyimide composite films prepared in Examples 1 to 4 and Comparative Examples 1 to 4, adhesive strength to a metal, tensile strength, modulus, and coefficient of thermal expansion were measured. Results are shown in Table 3.

1) Adhesive Strength

Copper was sputtered on a surface of one second polyimide layer of each of the polyimide composite films prepared in Examples 1 to 4 and Comparative Examples 1 to 4, thereby forming a copper layer, followed by cutting a surface of the film along a cross cutter guide to form a grid pattern.

Thereafter, the surface of the film was rubbed with a brush or the like, followed by measurement of 90 degree peel strength at room temperature by detaching a cross cutting tape (3M company) from the grid pattern subsequent to attachment of the tape to the grid pattern.

2) Modulus

Modulus was measured using a universal testing machine (INSTRON model 5564) in accordance with ASTM D882.

3) Tensile Strength

Tensile strength was measured in accordance with ASTM D882.

4) Coefficient of Thermal Expansion

Coefficient of thermal expansion was measured using a thermomechanical analyzer (TMA).

TABLE 3

| | | | | Coefficient |
|---|---|---|---|---|
| | Adhesive | | Tensile | of thermal |
| | strength | Modulus | strength | expansion |
| | (kgf/mm²) | (GPa) | (GPa) | (μm/m · ° C.) |
| Example 1 | 0.60 | 6.4 | 0.49 | 4.6 |
| Example 2 | 0.65 | 6.5 | 0.49 | 4.4 |
| Example 3 | 0.9 | 6.8 | 0.51 | 4.5 |
| Example 4 | 0.64 | 7.6 | 0.48 | 2.2 |
| Comparative | 0.45 | 6.5 | 0.49 | 4.6 |
| Example 1 | | | | |
| Comparative | 0.53 | 6.4 | 0.48 | 4.6 |
| Example 2 | | | | |
| Comparative | 0.43 | 5.6 | 0.43 | 4.3 |
| Example 3 | | | | |
| Comparative | 0.9 | 6.8 | 0.51 | 4.8 |
| Example 4 | | | | |

From the results shown in Table 3, it can be seen that the polyimide composite films according to Examples 1 to 4 had high levels of modulus and tensile strength while exhibiting good adhesion to a metal and thus could avoid deterioration in mechanical properties due to the inorganic powder and the coupling agent. Particularly, the polyimide composite film according to Example 4 had a coefficient of thermal expansion of 2.2 μm/m·° C. and thus could be advantageously used in implementation of a flexible circuit board.

Conversely, it can be seen that the polyimide composite films according to Comparative Examples 1 to 4 exhibited poor adhesion to a metal or had extremely low tensile strength or modulus. Particularly, the film of Comparative Example 1, free from the coupling agent, exhibited very poor adhesion to a metal at room temperature, and the films of Comparative Examples 2 and 3, including the coupling agent or the inorganic powder in amounts outside the ranges defined in the present invention, failed to have desired levels of both adhesion to a metal at room temperature and mechanical properties. In addition, the film of Comparative Example 4, including an excess of the inorganic powder, had a haze of 12% or more and thus exhibited poor properties in terms of transparency.

From these results, it can be seen that use of the coupling agent and the inorganic powder in amounts falling within the ranges defined in the present invention is critical to implementation of a desired polyimide composite film.

Although some embodiments have been described herein, it should be understood that various modifications, changes, alterations, and equivalent embodiments can be made by those skilled in the art without departing from the spirit and scope of the invention.

### INDUSTRIAL APPLICABILITY

A polyimide composite film according to the present invention may be characterized in that at least 90%, specifically at least 99% of the total weight of an inorganic powder and at least 90%, specifically at least 99% of the total weight of a coupling agent are present in a second polyimide layer forming a surface layer of the composite film.

Accordingly, for example, a metal layer formed on the second polyimide layer of the polyimide composite film by sputtering can interact with the inorganic powder and the coupling agent mostly present in the second polyimide layer, whereby the polyimide composite film can have excellent adhesion to the metal layer.

In addition, since the coupling agent and the inorganic powder are concentrated in the surface layer of the composite film, at which the coupling agent and the inorganic powder will be more likely to interact with the metal layer, through use of limited amounts of the coupling agent and the inorganic powder, it is possible to achieve both sufficient adhesive strength of the polyimide composite film and suppression of deterioration in mechanical properties of the film due to the inorganic powder and the coupling agent.

If the coupling agent and the inorganic powder are present at an inner portion of the polyimide composite film, mechanical properties of the polyimide composite film can be greatly deteriorated. However, according to the present invention, structural characteristics of the polyimide composite film as described above and the presence of a first polyimide layer can minimize deterioration in mechanical properties of the composite film.

1. A polyimide composite film comprising:
a first polyimide layer derived from a first polyamic acid solution;
at least one second polyimide layer derived from a second polyamic acid solution and formed on one or both surfaces of the first polyimide layer;
an inorganic powder; and
a coupling agent,
wherein at least 90% of the total weight of the inorganic powder and at least 90% of the total weight of the coupling agent are present in the second polyimide layer, and
wherein the polyimide composite film has an adhesive strength of 0.6 kgf/mm² or more, as measured with respect to a metal layer at room temperature, a tensile strength of 0.45 GPa or more, and a modulus of 6.0 GPa or more.

2. The polyimide composite film according to claim 1, wherein at least 99% of the total weight of the inorganic powder and at least 99% of the total weight of the coupling agent are present in the second polyimide layer.

3. The polyimide composite film according to claim 1, wherein the inorganic powder comprises at least one metal powder selected from the group consisting of nickel, chromium, iron, aluminum, copper, titanium, silver, gold, cobalt, manganese, zirconium, and alloys thereof.

4. The polyimide composite film according to claim 1, wherein the inorganic powder has an average particle diameter (D50) of 0.1 μm to 2 μm.

5. The polyimide composite film according to claim 1, wherein the coupling agent comprises at least one selected from the group consisting of a titanate coupling agent, an organic chrome complex coupling agent, a silane coupling agent, and an aluminate coupling agent.

6. The polyimide composite film according to claim 1, wherein the polyimide composite film has a structure in which the second polyimide layer is formed on one surface of the first polyimide layer, the second polyimide layer comprising 0.02 wt % to 2 wt % of the inorganic powder based on the total weight of the polyimide composite film and 200 ppm to 1,000 ppm of the coupling agent based on the total weight of the second polyimide layer.

7. The polyimide composite film according to claim 1, wherein the polyimide composite film comprises a pair of second polyimide layers respectively formed on opposite surfaces of the first polyimide layer, the second polyimide layers each comprising 200 ppm to 1,000 ppm of the coupling agent based on the total weight thereof and 0.02 wt % to 2 wt % of the inorganic powder based on the total weight of the polyimide composite film.

8. The polyimide composite film according to claim 1, wherein the first polyamic acid solution and the second polyamic acid solution are prepared using the same monomer combination or different monomer combinations, the monomer combination comprising at least one dianhydride monomer and at least one diamine monomer.

9. The polyimide composite film according to claim 8, wherein, upon preparation of the first polyamic acid solution and the second polyamic acid solution using the same monomer combination, the dianhydride monomer comprises pyromellitic dianhydride (PMDA) and further comprises 3,3′,4,4′-biphenyltetracarboxylic dianhydride (s-BPDA) or 2,3,3′,4′-biphenyltetracarboxylic dianhydride (a-BPDA), and the diamine monomer comprises 1,4-diaminobenzene (paraphenylene diamine, PDA, PPD) and 4,4′-diaminodiphenyl ether (oxydianiline, ODA).

10. The polyimide composite film according to claim 1, wherein the polyimide composite film has an average thickness of 15 μm to 100 μm.

11. A method of preparing the polyimide composite film according to claim 1, comprising:
preparing a first composition comprising the first polyamic acid solution and a second composition comprising the second polyamic acid solution, the inorganic powder, and the coupling agent;
supplying the first and second compositions to a multilayer co-extrusion die and co-extruding the first and second compositions using the co-extrusion die such that the first and second compositions are stacked one above another; and
imidizing the co-extruded first and second compositions.

12. The method according to claim 11, wherein:
co-extruding the first and second compositions comprises co-extruding the first and second compositions onto a support such that the second composition, the first composition, and the second composition are sequentially stacked on the support and performing primary heat treatment of the co-extruded first and second compositions at a temperature of 50° C. to 200° C.; and
imidizing the co-extruded first and second compositions comprises performing secondary heat treatment of the first and second compositions subjected to the primary heat treatment at a temperature of 200° C. to 700° C.,
wherein the polyimide composite film has a structure in which the second polyimide layer derived from the second composition is formed on both surfaces of the first polyimide layer derived from the first composition.

13. The method according to claim 11, wherein:
co-extruding the first and second compositions comprises co-extruding the first and second compositions onto a support such that the second composition and the first composition are sequentially stacked on the support and performing primary heat treatment of the co-extruded first and second compositions at a temperature of 50° C. to 200° C.; and
imidizing the co-extruded first and second compositions comprises performing secondary heat treatment of the first and second compositions subjected to the primary heat treatment at a temperature of 200° C. to 700° C.,
wherein the polyimide composite film has a structure in which the second polyimide layer derived from the second composition is formed on one surface of the first polyimide layer derived from the first composition.

14. The method according to claim 11, wherein, in the process of conversion of the second polyamic acid solution in the second composition into a polyimide resin through ring closure and dehydration, the inorganic powder and the coupling agent interact with the polyimide resin to be bound thereto.

15. An electronic component comprising the polyimide composite film according to claim 1 as an insulating film.

16. The electronic component according to claim 15, wherein the electronic component is a semiconductor device or a flexible circuit board.

17. The electronic component according to claim 16, wherein the flexible circuit board comprises:
the polyimide composite film; and
a metal layer deposited on a surface of the second polyimide layer of the polyimide composite film by sputtering copper.
